(19) United States
(12) Patent Application Publication
(10) Pub. No.: US 2023/0161729 A1
(43) Pub. Date: May 25, 2023

(54) Detection System for PCIe CEM Connection Interface of Circuit Board and Method Thereof

(71) Applicants: Inventec (Pudong) Technology Corporation, Shanghai (CN); Inventec Corporation, Taipei City (TW)

(72) Inventor: Tian-Chao Zhang, Shanghai (CN)

(21) Appl. No.: 17/554,307

(22) Filed: Dec. 17, 2021

(30) Foreign Application Priority Data
Nov. 22, 2021 (CN) 202111388865.6

(51) Int. Cl. G06F 13/42

(52) U.S. Cl. CPC G06F 13/4282; G06F 2213/0026

(57) ABSTRACT

A detection system for PCIe CEM connection interface of the circuit board and a method thereof are disclosed. In the detection system, a test adapter card implements transformation of a PCIe CEM connection interface, a PCIe chip of a test card generates differential status information based on a differential signal obtained by a test-card MCIO connection interface; the to-be-tested circuit board or the external test device loads and executes a test program to obtain differential status information, to implement detection of the differential signal of the at least one PCIe CEM slot, thereby achieving the technical effect of implementing detection for the differential signal of the PCIe CEM connection interface through the test adapter card and the test card.

### CROSS-REFERENCE TO RELATED APPLICATION

This application claims the benefit of Chinese Application Serial No. 202111388865.6, filed Nov. 22, 2021, which is hereby incorporated herein by reference in its entirety.

### BACKGROUND OF THE INVENTION

### 1. Field of the Invention

The present invention is related to a detection system and a method thereof, and more particularly to a detection system capable of implementing detection for differential signal of the PCIe Card Electromechanical (GEM) connection interface through a test adapter card and a test card, and a method thereof.

### 2. Description of the Related Art

The existing detecting method for peripheral component interconnect express (abbreviated as PCIe) card electromechanical (abbreviated as CEM) connection interfaces on a circuit board is generally to respectively plug different function test cards into the PCIe CEM connection interfaces to test the functions of the PCIe CEM connection interfaces. Each PCIe CEM connection interface needs to be plugged with a function test card, so a large number of function test cards are required to complete the existing detecting method for different functions of the PCIe CEM connection interfaces.

However, in fact, it only needs to detect electrical characteristics of the PCIe CEM connection interface to ensure its production quality, and the detection for the electrical characteristics of the PCIe CEM connection interface needs to detect signal link and high-frequency characteristics only and does not need to perform data transmission detection. Therefore, the existing; detection method for PCIe CEM connection interface should be improved with the times. The method of using multiple adapter test cards and single test card to perform the detection for PCIe CEM connection interface will be a desired solution.

According to the above-mentioned contents, what is needed is to develop an improved solution to solve the conventional problem that the conventional method detecting the PCIe CEM connection interface of the circuit board with full data transmission detection is inconvenient.

### SUMMARY OF THE INVENTION

An objective of the present invention is to disclose a detection system for PCIe CEM connection interface of the circuit board and a method thereof, so as to solve the conventional technology problem that the conventional method detecting the PCIe CEM connection interface of the circuit board with full data transmission detection is inconvenient.

In order to achieve the objective, the present invention discloses a detection system for PCIe CEM connection interface of the circuit board, and the detection system includes a to-be-tested circuit board, at least one test adapter card, a test card and an external test device.

The to-be-tested circuit board includes at least one PCIe CEM slot; a central processing unit electrically connected to the at least one PCIe CEM slot, wherein the central processing unit generates and provides a differential signal through one of the at least one PCIe CEM slot. Each of the at least one test adapter card includes a PCIe CEM plug interface plugged to one of the at least one PCIe CEM slot, configured to obtain the differential signal, from the corresponding one of the at least one PCIe CEM slot; a communication unit electrically connected to the at least one PCIe CEM plug interface, and configured to provide the differential signal obtained by the PCIe CEM plug interface; and at least one adapter MCIO connection interface electrically connected to the communication unit, and configured to provide the differential signal, which is obtained by the communication unit through the PCIe CEM plug interface.

The test card includes at least two test-card MCIO connection interfaces configured to determine an electrical connection mode of the at least one adapter MCIO connection interface and the at least two test-card MCIO connection interfaces based on a bandwidth of the plugged one of the at least one PCIe CEM slot through a MCIO connection line, wherein each of the at least two test-card MCIO connection interfaces obtain the differential signal from one of the at least one adapter MCIO connection interface connected thereto; a test-card serial data communication standard interface electrically connected to the circuit-data communicate standard interface; a test-card network connection interface electrically connected to the circuit-board network connection interface; a PCIe chip electrically connected to the at least two test-card MCIO connection interfaces, the test-card serial data communication standard interface and the test-card network connection interface, wherein the PCIe chip generates differential status information according to the differential signal obtained by the at least two test-card MCIO connection interfaces, and provides the differential status information through the test-card serial data communication standard interface or the test-card network connection interface.

The external test device includes a device serial-data communication standard interface electrically connected to the test-card serial data communication standard interface;

a device network connection interface electrically connected to the test-card network connection interface; a device storage unit configured to store a test program; a device central-processing unit electrically connected to the at least two device serial-data communication standard interface, the device network connection interface and the device storage unit, wherein the device central-processing unit loads and executes the test program stored in the storage unit, the test program obtains the differential status information from the PCIe chip through the device serial-data communication standard interface and/or the device network connection interface, to implement detection for the differential signal of the at least one PCIe CEM slot.

In order to achieve the objective, the present invention discloses a detection method for PCIe CEM connection interface of circuit board, and the detection method includes steps of: providing a to-be-tested circuit board comprising at least one PCIe CEM slot and a central processing unit; electrically connecting the central processing unit to the at least one PCIe CEM slot; providing at least one test adapter card, wherein each of the at least one test adapter card comprises a PCIe CEM plug interface, a communication unit, and at least one adapter MCIO connection interface; plugging the PCIe CEM plug interface into one of the at least one PCIe CEM slot; electrically connecting the communication unit to the PCIe CEM plug interface; electrically connecting the adapter MCIO connection interface to the communication unit; providing a test card comprising at least two test-card MCIO connection interfaces, a PCIe chip, a test-card serial data communication standard interface and a test-card network connection interface; determining an electrical connection mode of the adapter MCIO connection interface and the at least two test-card MCIO connection interfaces based on a bandwidth of the plugged one of the at least one PCIe CEM slot through a MCIO connection line, by the at least two test-card MCIO connection interface; electrically connecting the PCIe chip to the at least two test-card MCIO connection interface, the test-card serial data communication standard interface and the test-card network connection interface; providing an external test device comprising a device serial-data communication standard interface, a device network connection interface, a device storage unit and a device central-processing unit; electrically connecting the device serial-data communication standard interface to the test-card serial data communication standard interface; electrically connecting the device network connection interface to the test-card network connection interface; storing a test program in the device storage unit; electrically connecting the device central-processing unit to the device serial-data communication standard interface, the device network connection interface and the device storage unit; loading and executing the test program stored in the storage unit, by the device central-processing unit; generating a differential signal by the central processing unit; providing the differential signal to the PCIe CEM plug interface, through one of the at least one PCIe CEM slot, by the central processing unit; providing the differential signal, obtained by the PCIe CEM plug interface, to the adapter MCIO connection interface by the communication unit; obtaining the differential signal from the connected adapter MCIO connection interface, by the at least two test-card MCIO connection interface; generating differential status information by the PCIe chip, according to the differential signal obtained by the test-card MCIO connection interface; obtaining the differential status information from the PCIe chip, through at least one of the device serial-data communication standard interface and the device network connection interface, by the test program, to implement detection of the differential signal of the at least one PCIe CEM slot.

According to the above-mentioned content, the technical solution of the present invention is able to achieve the technical effect of implementing detection for differential signal of the PCIe CEM connection interface through a test adapter card and a test card.

### BRIEF DESCRIPTION OF THE DRAWINGS

The structure, operating principle and effects of the present invention will be described in detail by way of various embodiments which are illustrated in the accompanying drawings.

FIG. 1 is a block diagram of a test adapter card of the present invention.

FIG. 2 illustrates a schematic view of a to-be-tested circuit board, a test adapter card and a test card electrically connected to each other, according to a first embodiment of the present invention.

FIG. 3 is a schematic view of a to-be-tested circuit board, a test adapter card, a test card and an external test device electrically connected to each other, according to a second embodiment of the present invention.

FIGS. 4A to 4C are flowcharts of a detection method, according to a first embodiment of the present invention.

FIG. 5A to 5C are flowcharts of a detection method, according to a second embodiment of the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims.

These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts. As used herein, the singular forms “a”, “an” and “the” are intended to include the plural forms as well, unless the context clearly indicates otherwise.

It is to be acknowledged that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and. all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the words “comprise” and “include”, and variations such as “comprises”, “comprising”, “includes”, or “including”, will be acknowledged to imply the inclusion of stated elements but not the exclusion of any other elements.

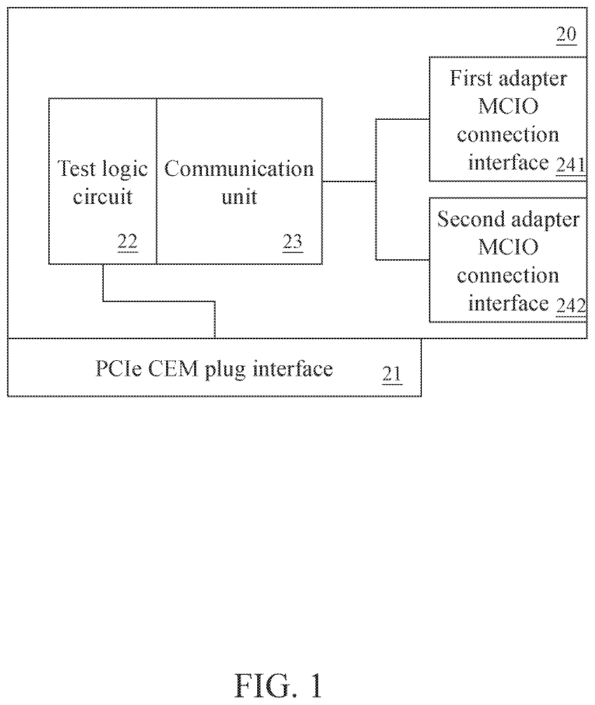

Please refer to FIG. 1, which is a block diagram of a test adapter card of the present invention.

As shown in Fig , a test adapter card 20 includes a PCIe CEM plug interface 21, a test logic circuit 22, a communication unit 23, a first adapter MCIO connection interface 241 and a second adapter MCIO connection interface 242. The PCIe CEM plug interface 21 is electrically connected to the test logic circuit 22, the test logic circuit 22 is electrically connected to the communication unit 23, the communication unit 23 is electrically connected to the first adapter MCIO connection interface 241 and the second adapter MCIO connection interface 242, and the PCIe CEM plug interface 21 is electrically connected to the communication unit 23. The PCIe Card Electromechanical (abbreviated as CEM) is an interface specification of PCIe.

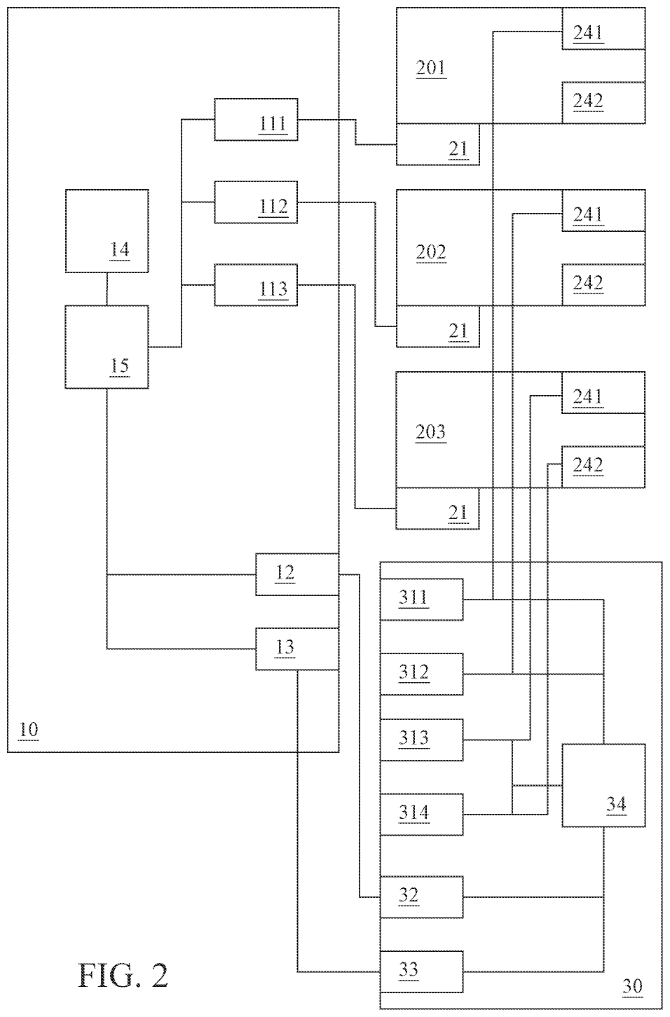

Please refer to FIG. 2, which illustrates a schematic view of a to-be-tested circuit board, a test adapter card and a test card electrically connected to each other, according to a first embodiment of the present invention.

According to a first embodiment of the present invention, the detection system includes a to-be-tested circuit board 10, a first test adapter card 201, a second test adapter card 202, a third test adapter card 203, and a test card 30. The to-be-tested circuit board 10 includes a first PCIe CEM slot 111, a second. PCIe CEM slot 112, a third. PCIe CEM slot 113, a circuit-data communicate standard interface 12, a circuit-board network (NET) connection interface 13, a storage unit 14, and a central processing unit 15. The test card 30 includes a first test-card MCIO connection interface 311, a second test-card MCIO connection interface 312, a third test-card MCIO connection interface 313, a fourth test-card MCIO connection interface 314, a test-card serial data communication standard interface 32, a test-card network connection interface 33, and a PCIe chip 34.

The bandwidths of the first PCIe CEM slot 111, the second. PCIe CEM slot 112 and the third PCIe CEM slot 113 are X8, X8 and X16, respectively. The first test adapter card 201 is plugged into the first PCIe CEM slot 111 to form electrical connection, the second test adapter card 202 is plugged into the second PCIe CEM slot 112 to form electrical connection, the third test adapter card 203 is plugged into the third PCIe CEM slot 113 to form electrical connection. The first PCIe CEM slot 111, the second PCIe CEM slot 112, the third PCIe CEM slot 113, the circuit-data communicate standard interface 12, the circuit-board network connection interface 13, the storage unit 14 and the central processing unit 15 are electrically connected to each other.

The first test-card MCIO connection interface 311, the second test-card MCIO connection interface 312, the third test-card. MCIO connection interface 313, the fourth test-card MCIO connection interface 314, the test-card serial data communication standard interface 32 and the test-card network connection interface 33 are electrically connected to the PCIe chip 34.

The bandwidth of the first PCIe CEM slot 111 plugged with the first test adapter card 201 is X8, so the first adapter MCIO connection interface 241 (or the second adapter MCIO connection interface 242) of the first test adapter card 201 can be used to electrically connect to the first test-card. MCIO connection interface 311 through a MCIO connection line; the bandwidth of the second PCIe CEM slot 112 plugged with the second test adapter card 202 is X8, so the second adapter MCIO connection interface 242 (or the first adapter MCIO connection interface 241) of the second test adapter card 202 can be used to electrically connected to the second test-card MCIO connection interface 312 through a MCIO connection line; the bandwidth of the third PCIe CEM slot 113 plugged with the third test adapter card 203 is X16, so the first adapter MCIO connection interface 241 and the second adapter MCIO connection interface 242 of the third test adapter card 203 are required to respectively electrically connect to the third test-card MCIO connection interface 313 and the fourth test-card MCIO connection interface 314 through MCIO connection lines at the same time.

The circuit-data communicate standard interface 12 is electrically connected to the test-card serial data communication standard interface 32, and the circuit-board network connection interface 13 is electrically connected to the test-card network connection interface 33.

The central processing unit 15 loads and executes a test program stored in the storage unit 14, to generate and provide a differential signal to the first test adapter card 201, the second test adapter card 202 or the third test adapter card 203 through the first PCIe CEM slot 111, the second PCIe CEM slot 112 or the third PCIe CEM slot 113, respectively.

The PCIe CEM plug interface 21 of the first test adapter card 201, the second test adapter card 202 or the third test adapter card 203 respectively obtains the differential signal from the first PCIe CEM slot 111, the second PCIe CEM slot 112 or the third PCIe CEM slot 113, and the differential signal is then provided to at least one of the first adapter MCIO connection interface 241 and the second adapter MCIO connection interface 242 through the test logic circuit 22 and the communication unit 23.

The first test-card MCIO connection interface 311, the second test-card MCIO connection interface 312, the third test-card MCIO connection interface 313 and/or the fourth test-card MCIO connection interface 314 can obtain the differential signal from the corresponding one of the first test adapter card 201, the second test adapter card 202 or third test adapter card 203, the PCIe chip 34 can generates differential status information based on the differential signal. The differential status information generated by the PCIe chip 34 is provided to the circuit-data communicate standard interface 12 and/or the circuit-board network connection interface 13 through the test-card serial data communication standard interface 32 and/or the test-card network connection interface 33, and the test program obtains the differential status information through the circuit-data communicate standard interface 12 and/or the circuit-board network connection interface 13, so as to implement the detection for differential signal of the first PCIe CEM slot 111, the second PCIe CEM slot 112 or the third PCIe CEM slot 113.

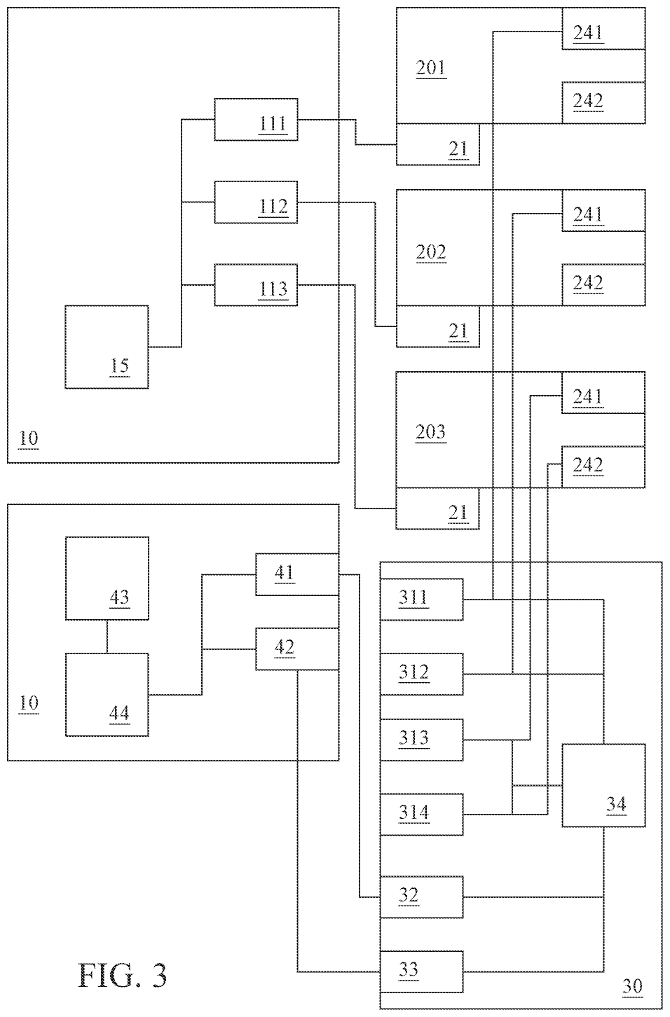

Please refer to FIG. 3, which is a schematic view of a to-be-tested circuit board, a test adapter card, a test card and an external test device electrically connected to each other, according to a second embodiment of the present invention.

According to the second embodiment of the present invention, the detection system includes a to-be-tested circuit board 10, a first test adapter card 201, a second test adapter card 202, a third test adapter card 203, a test card 30 and an external test device 40; in second embodiment, the to-be-tested circuit board 10 also includes a first PCIe CEM slot 111, a second PCIe CEM slot 112, a third PCIe CEM slot 113, and a central processing unit 15. The test card 30 includes a first test-card MCIO connection interface 311, a second test-card MCIO connection interface 312, a third test-card MCIO connection interface 313, a fourth test-card MCIO connection interface 314, a test-card serial data communication standard interface 32, a test-card network connection interface 33, and a PCIe chip 34. The external test device 40 includes a device serial-data communication standard interface 41, a device network connection interface 42, a device storage unit 43 and a device central-processing unit 44.

A part of the second embodiment is the same as that of the first embodiment and the description of the part can refer to the first embodiment, so detailed description is not repeated herein. The difference between the first embodiment and the second embodiment is that the second embodiment includes an external test device 40, and the external test device 40 can be, for example, a general computer, a smart device, or a server; however, these examples are merely for exemplary illustration, and the application field of the present invention is not limited to these examples.

The central processing unit 15 autonomously generates the differential signal, or the device central-processing unit 44 loads and executes the test program stored in the device storage unit 43 to generate a command and provide the command to the to-be-tested circuit board 10 through the test card 30 and the to-be-tested circuit board 10, and at least one of the first test adapter card 201, the second test adapter card 202 and the third test adapter card 203, and the central processing unit 15 generates a differential signal according to the command; however, these examples are merely for exemplary illustration, and the application field of the present invention is not limited to these examples.

The PCIe chip 34 generates differential status information based on the differential signal. The differential status information generated by the PCIe chip 34 is provided to the device serial-data communication standard interface 41 and/or the device network connection interface 42, through the test-card serial data communication standard interface 32 and/or the test-card network connection interface 33. The test program obtains the differential status information through the device serial-data communication standard interface 41 and/or the device network connection interface 42, so as to implement the detection for the differential signal of the first PCIe CEM slot 111, the second PCIe CEM slot 112 or the third. PCIe CEM slot 113.

In the first embodiment and the second embodiment, the test program can generate a detection signal, and the test program provides the detection signal to the first test adapter card 201, the second test adapter card 202 or the third test adapter card 203, so that the test logic circuit 22 of the first test adapter card 201, the second test adapter card 202 or the third test adapter card 203 can perform signal link detection and pin status detection for the first PCIe CEM slot 111, the second PCIe CEM slot 112 or the third. PCIe CEM slot 113; or the test logic circuit 22 of the first test adapter card 201, the second test adapter card 202 or the third test adapter card 203 can perform detections for status reading, power-pin voltage measurement and/or wake signal transmission of the first PCIe CEM slot 111, the second PCIe CEM slot 112 or the third. PCIe CEM slot 113 based on the detection signal through the first PCIe CEM slot 111, the second PCIe CEM slot 112 or third PCIe CEM slot 113, so as to generate a detection result. The first test adapter card 201, the second test adapter card 202 or the third test adapter card 203 then sends the detection result back to the test program through the test-card serial data communication standard interface 32 and/or the test-card network connection interface 33 of the test card 30, so as to implement detection for the non-differential signal pin of the first PCIe CEM slot 111, the second PCIe CEM slot 112 and/or the third PCIe CEM slot 113. The detection for each non-differential signal pin will be particularly described in the following paragraphs.

Each of the first PCIe CEM slot 111, the second PCIe CEM slot 112 and the third PCIe CEM slot 113 is presented as a PCIe in the test program, and a downstream port of each PCIe is electrically connected to a register which stores the characteristics and status of the corresponding one of the first PCIe CEM slot 111, the second PCIe CEM slot 112 and the third PCIe CEM slot 113. The test program performs the signal link detection and pin status detection by reading the status of the register corresponding to the detected one of the first PCIe CEM slot 111, the second PCIe CEM slot 112 and the third PCIe CEM slot 113. For example, the signal link detection and the pin status detection include detections for PCIe Link Speed, Link Width, and Link Speed Change.

The test logic circuit 22 of the first test adapter card 201, the second test adapter card 202 or the third test adapter card 203 performs voltage measurement on a power pin of the corresponding one of the first PCIe CEM slot 111, the second PCIe CEM slot 112 and the third PCIe CEM slot 113, and then sends a voltage measurement result of the power pin of the first test adapter card 201, the second test adapter card 202 or the third test adapter card 203 to the test program through the test-card serial data communication standard interface 32 and/or the test-card network connection interface 33 of the test card 30, so as to implement the detection for power pin status of the first PCIe CEM slot 111, the second. PCIe CEM slot 112 and the third PCIe CEM slot 113.

The test logic circuit 22 of the first test adapter card 201, the second test adapter card 202 or the third test adapter card 203 can includes an EEPROM, the test program can read the EEPROM of the first test adapter card 201, the second test adapter card 202 or the third test adapter card 203 through the system management bus (SNIBus), to perform the signal link detection.

The first test adapter card 201, the second test adapter card 202 or the third test adapter card 203 can transmit a wake signal in response to the detection signal, a baseboard management controller (BMC) or an I/O controller hub (ICH) of the test card 30 reads the wake signal to perform signal link detection for the corresponding one of the first test adapter card 201, the second test adapter card 202 and the third test adapter card 203.

In an embodiment, a pull-up resistor and a pull-down resistor can be disposed between one of the first PCIe CEM slot 111, the second. PCIe CEM slot 112 and the third PCIe CEM slot 113 and the corresponding one of the first test adapter card 201, the second test adapter card 202 and the third test adapter card 203. The first test adapter card 201, the second test adapter card 202 or the third test adapter card 203 can read a signal status of the input/output pin (such as TMS, TDI, TDO, TCK, PWRBRK or CLKREQ pin) in the first PCIe CEM slot 111, the second PCIe CEM slot 112 and the third. PCIe CEM slot 113 by controlling the pull-up resistor and the pull-down resistor to be at one of a pull-up status, a pull-down status and a non-up-down status, so as to detect the status of the input/output pin at a high logic level, a low logic level status or a NC status.

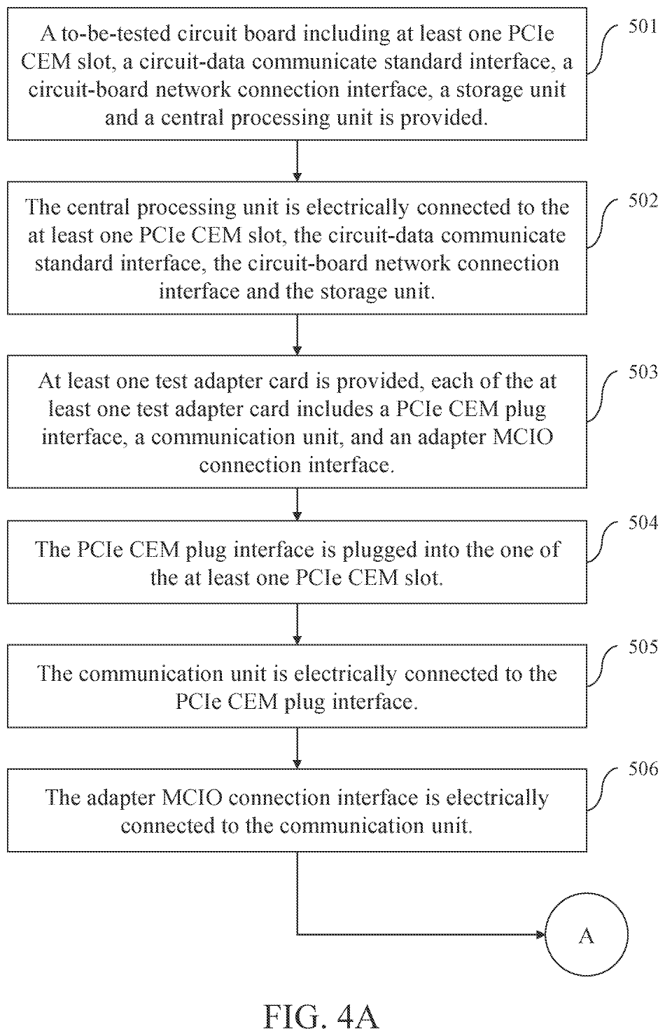

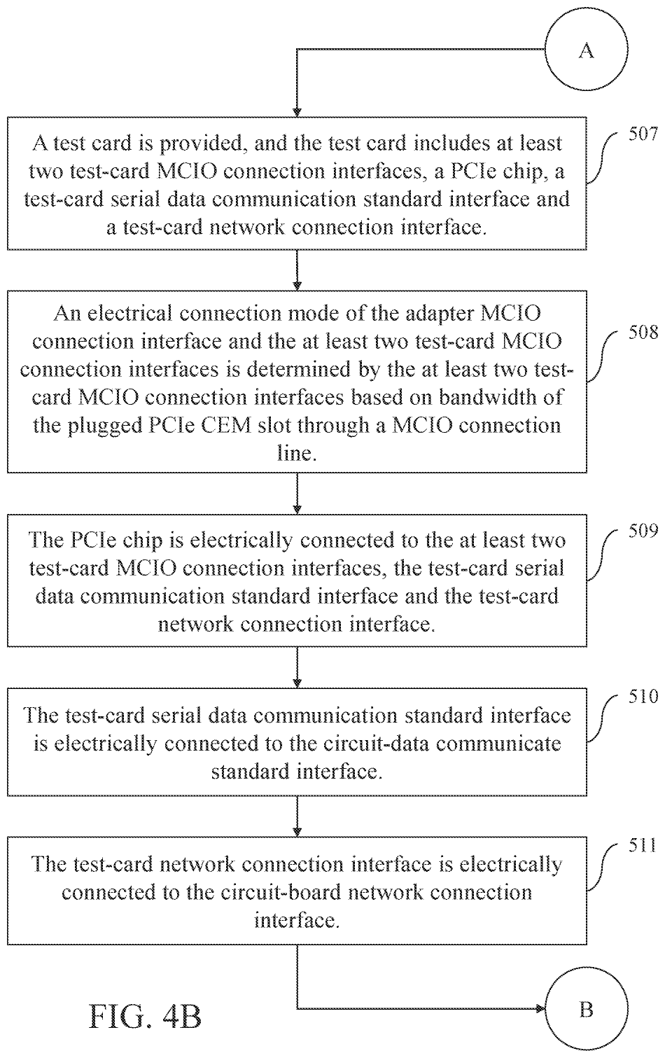

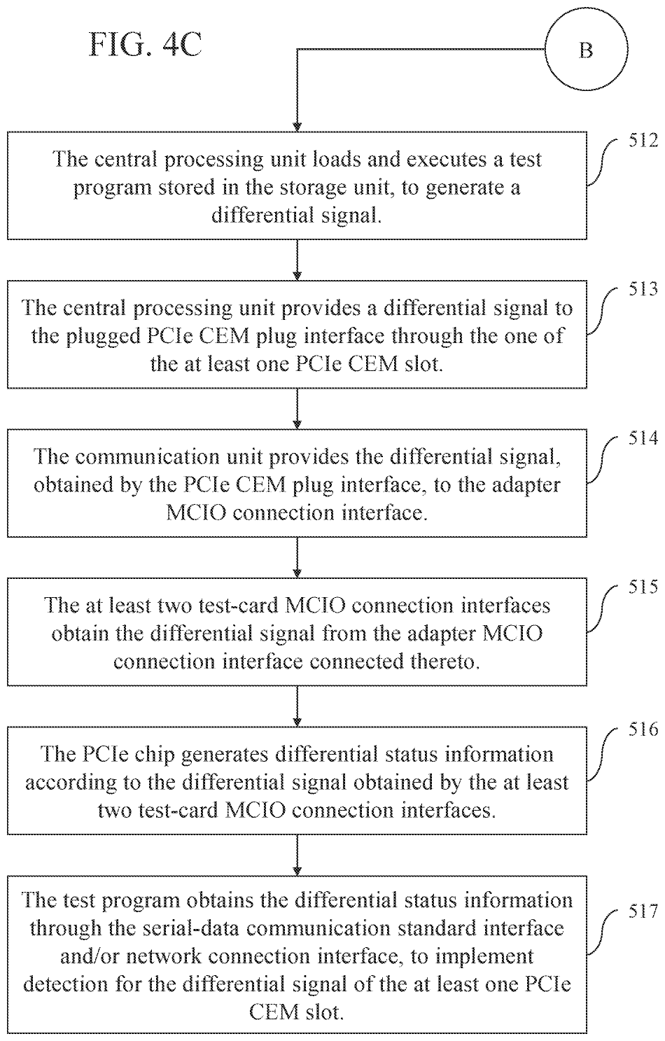

Please refer to FIGS. 4A to 4C, which are flowcharts of a detection method, according to a first embodiment of the present invention.

According to a first embodiment of the present invention, the detection method for PCIe CEM connection interface of circuit board can include steps 501 to 517.

In a step 501, a to-be-tested circuit board including at least one PCIe CEM slot, a circuit-data communicate standard interface, a circuit-board network connection interface, a storage unit and a central processing unit is provided. In a step 502, the central processing unit is electrically connected to the at least one PCIe CEM slot, the circuit-data communicate standard interface, the circuit-board network connection interface and the storage unit. In a step 503, at least one test adapter card is provided, each of the at least one test adapter card includes a PCIe CEM plug interface, a communication unit, and an adapter MCIO connection interface. In a step 504, the PCIe CEM plug interface is plugged into the one of the at least one PCIe CEM slot. In a step 505, the communication unit is electrically connected to the PCIe CEM plug interface. In a step 506, the adapter MCIO connection interface is electrically connected to the communication unit. In a step 507, a test card is provided, and the test card includes at least two test-card MCIO connection interfaces, a PCIe chip, a test-card serial data communication standard interface and a test-card network connection interface. In a step 508, an electrical connection mode of the adapter MCIO connection interface and the at least two test-card MCIO connection interfaces is determined by the at least two test-card MCIO connection interfaces based on bandwidth of the plugged PCIe CEM slot through a MCIO connection line. In a step 509, the PCIe chip is electrically connected to the at least two test-card MCIO connection interfaces, the test-card serial data communication standard interface and the test-card network connection interface. In a step 510, the test-card serial data communication standard interface is electrically connected to the circuit-data communicate standard interface. In a step 511, the test-card network connection interface is electrically connected to the circuit-board network connection interface. In a step 512, the central processing unit loads and executes a test program stored in the storage unit, to generate a differential signal. In a step 513, the central processing unit provides a differential signal to the plugged PCIe CEM plug interface through the one of the at least one PCIe CEM slot. In a step 514, the communication unit provides the differential signal, obtained by the PCIe CEM plug interface, to the adapter MCIO connection interface. In a step 515, the at least two test-card MCIO connection interfaces obtain the differential signal from the adapter MCIO connection interface connected thereto. In a step 516, the PCIe chip generates differential status information according to the differential signal obtained by the at least two test-card MCIO connection interfaces. In a step 517, the test program obtains the differential status information through the serial-data communication standard interface and/or network connection interface, so as to implement detection for the differential signal of the at least one PCIe CEM slot.

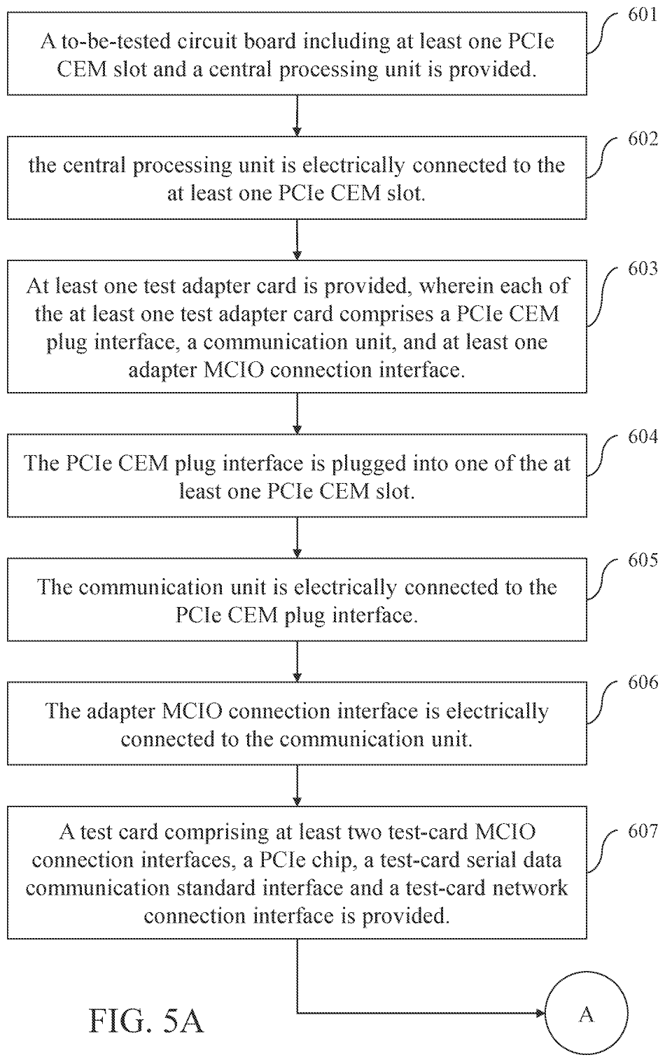

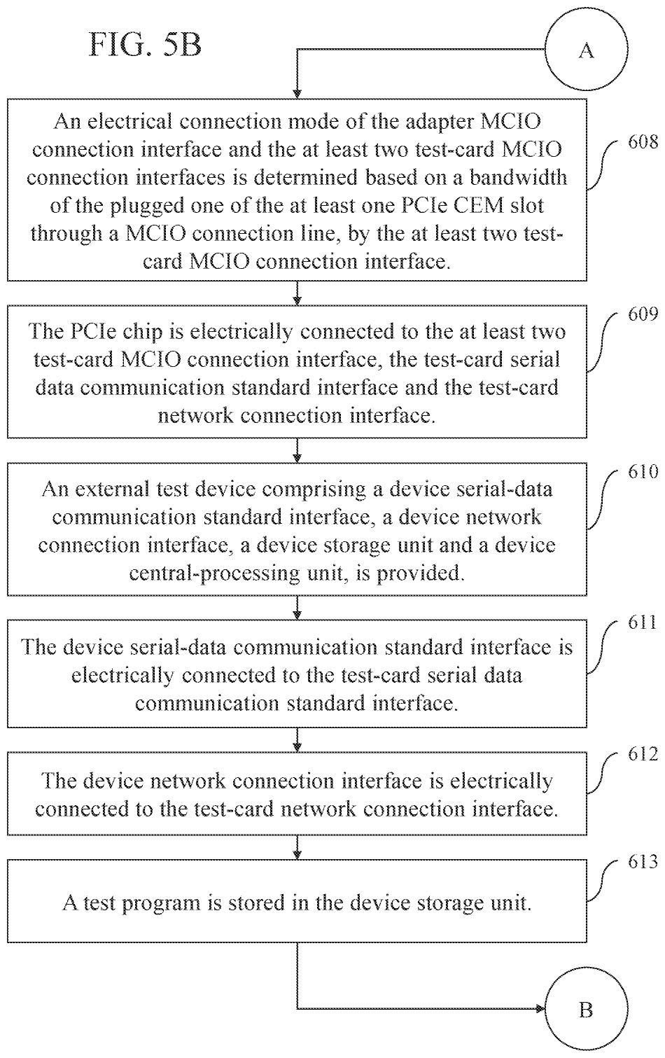

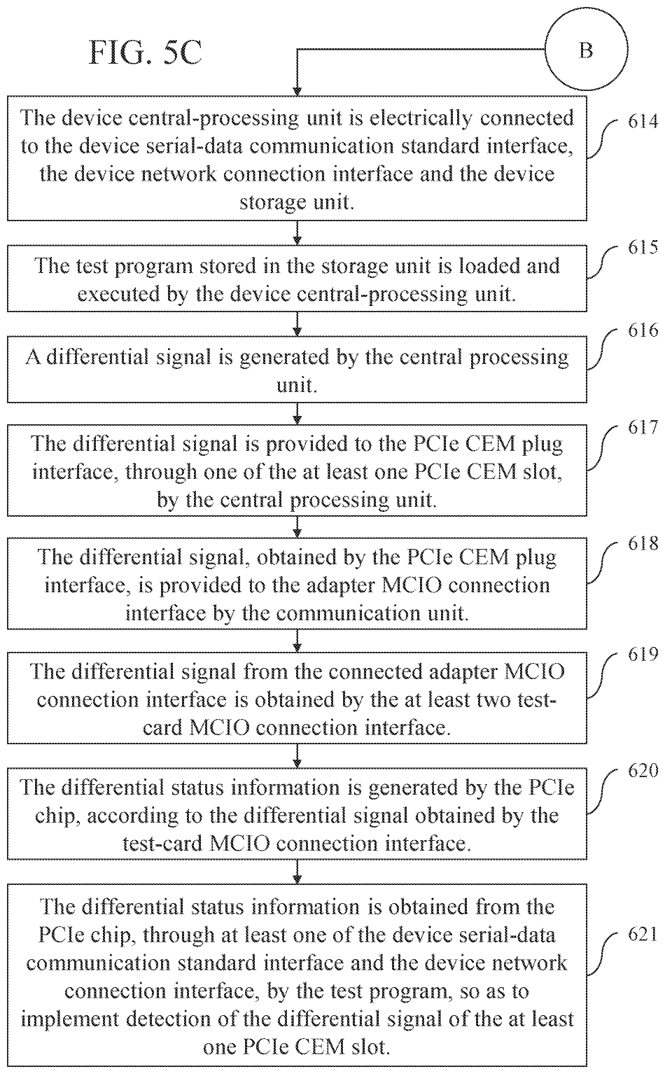

Please refer to FIGS. 5A to 5C, which illustrates flowcharts of a detection method for PCIe CEM connection interface of circuit board, according to a second embodiment of the present invention.

According to the second embodiment of the present invention, the detection method for PCIe CEM connection interface of circuit board includes steps 601 to 621.

In a step 601, a to-be-tested circuit board including at least one PCIe CEM slot and a central processing unit is provided. In a step 602, the central processing unit is electrically connected to the at least one PCIe CEM slot. In a step 603, at least one test adapter card is provided, wherein each of the at least one test adapter card comprises a PCIe CEM plug interface, a communication unit, and at least one adapter MCIO connection interface. In a step 604, the PCIe CEM plug interface is plugged into one of the at least one PCIe CEM slot. In a step 605, the communication unit is electrically connected to the PCIe CEM plug interface. In a step 606, the adapter MCIO connection interface is electrically connected to the communication unit. In a step 607, a test card comprising at least two test-card MCIO connection interfaces, a PCIe chip, a test-card serial data communication standard interface and a test-card network connection interface is provided. In a step 608, an electrical connection mode of the adapter MCIO connection interface and the at least two test-card MCIO connection interfaces is determined based on a bandwidth of the plugged one of the at least one PCIe CEM slot through a MCIO connection line, by the at least two test-card MCIO connection interface. In a step 609, the PCIe chip is electrically connected to the at least two test-card MCIO connection interface, the test-card serial data communication standard interface and the test-card network connection interface. In a step 610, an external test device comprising a device serial-data communication standard interface, a device network connection interface, a device storage unit and a device central-processing unit, is provided. In a step 611, the device serial-data communication standard interface is electrically connected to the test-card serial data communication standard interface. In a step 612, the device network connection interface is electrically connected to the test-card network connection interface. In a step 613, a test program is stored in the device storage unit. In a step 614, the device central-processing unit is electrically connected to the device serial-data communication standard interface, the device network connection interface and the device storage unit. In a step 615, the test program stored in the storage unit is loaded and executed by the device central-processing unit. In a step 616, a differential signal is generated by the central processing unit. In a step 617, the differential signal is provided to the PCIe CEM plug interface, through one of the at least one PCIe CEM slot, by the central processing unit. In a step 618, the differential signal, obtained by the PCIe CEM plug interface, is provided to the adapter MCIO connection interface by the communication unit. In a step 619, the differential signal from the connected adapter MCIO connection interface is obtained by the at least two test-card MCIO connection interface. In a step 620, differential status information is generated by the PCIe chip, according to the differential signal obtained by the test-card MCIO connection interface. In a step 621, the differential status information is obtained from the PCIe chip, through at least one of the device serial-data communication standard interface and the device network connection interface, by the test program, so as to implement detection of the differential signal of the at least one PCIe CEM slot.

According to above-mentioned contents, the difference between the present invention and the conventional technology is that the test adapter card implements transformation of the PCIe CEM connection interface, the PCIe chip of the test card generates the differential status information based on the differential signal obtained by the test-card MCIO connection interface, the to-be-tested circuit board or the external test device loads and executes the test program to obtain differential status information, to implement detection of the differential signal of the at least one PCIe CEM slot, thereby achieving the technical effect of implementing detection for the differential signal of the PCIe CEM connection interface through the test adapter card and the test card.

Therefore, the technical solution of the present invention is able to solve the conventional technology problem that the conventional method detecting the PCIe CEM connection interface of the circuit board with full data transmission detection is inconvenient, so as to achieve the technical effect of implementing detection for differential signal of the PCIe CEM connection interface through the test adapter card and the test card.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A detection system for PCIe CEM connection interface of circuit board, comprising:
a to-be-tested circuit board, comprising:
at least one PCIe CEM slot; and
a central processing unit electrically connected to the at least one PCIe CEM slot, wherein the central processing unit generates and provides a differential signal through one of the at least one PCIe CEM slot;
at least one test adapter card, wherein the each of the at least one test adapter card comprises:
a PCIe CEM plug interface plugged to one of the at least one PCIe CEM slot, configured to obtain the differential signal, from the corresponding one of the at least one PCIe CEM slot;
a communication unit electrically connected to the at least one PCIe CEM plug interface, and configured to provide the differential signal obtained by the PCIe CEM plug interface; and
at least one adapter MCIO connection interface electrically connected to the communication unit, and configured to provide the differential signal, which is obtained by the communication unit through the PCIe CEM plug interface;
a test card comprising:
at least two test-card MCIO connection interfaces configured to determine an electrical connection mode of the at least one adapter MCIO connection interface and the at least two test-card MCIO connection interfaces based on a bandwidth of the plugged one of the at least one PCIe CEM slot through a MCIO connection line, wherein each of the at least two test-card MCIO connection interfaces obtain the differential signal from one of the at least one adapter MCIO connection interface connected thereto;
a test-card serial data communication standard interface electrically connected to the circuit-data communicate standard interface;
a test-card network connection interface electrically connected to the circuit-board network connection interface; and
a PCIe chip electrically connected to the at least two test-card MCIO connection interfaces, the test-card serial data communication standard interface and the test-card network connection interface, wherein the PCIe chip generates differential status information according to the differential signal obtained by the at least two test-card MCIO connection interfaces, and provides the differential status information through the test-card serial data communication standard interface or the test-card network connection interface; and
an external test device, comprising:
a device serial-data communication standard interface electrically connected to the test-card serial data communication standard interface;
a device network connection interface electrically connected to the test-card network connection interface;
a device storage unit configured to store a test program; and
a device central-processing unit electrically connected to the at least two device serial-data communication standard interface, the device network connection interface and the device storage unit, wherein the device central-processing unit loads and executes the test program stored in the storage unit, the test program obtains the differential status information from the PCIe chip through the device serial-data communication standard interface and/or the device network connection interface, to implement detection for the differential signal of the at least one PCIe CEM slot.

2. The detection system for PCIe CEM connection interface of the circuit board according to claim 1, wherein each of the at least one test adapter card comprises a test logic circuit, the test logic circuit is electrically connected to the communication unit, the test program generates and provides a detection signal to the test logic circuit of the test adapter card through the test card, the test logic circuit performs detection based on the detection signal, to generate a detection result, or the test logic circuit performs detection for slot status reading, power-pin voltage measurement and/or wake signal transmission on corresponding one of the at least one PCIe CEM slot through a PCIe CEM plug interface based on the detection signal, to generate the detection result, and the test adapter card provides the detection result to the test program through the test card.

3. A detection method for PCIe CEM connection interface of circuit board, comprising:
providing a to-be-tested circuit board comprising at least one PCIe CEM slot and a central processing unit;
electrically connecting the central processing unit to the at least one PCIe CEM slot;
providing at least one test adapter card, wherein each of the at least one test adapter card comprises a PCIe CEM plug interface, a communication unit, and at least one adapter MOO connection interface;
plugging the PCIe CEM plug interface into one of the at least one PCIe CEM slot;
electrically connecting the communication unit to the PCIe CEM plug interface;
electrically connecting the adapter MCIO connection interface to the communication unit;
providing a test card comprising at least two test-card MCIO connection interfaces, a PCIe chip, a test-card serial data communication standard interface and a test-card network connection interface;
determining an electrical connection mode of the adapter MOO connection interface and the at least two test-card MCIO connection interfaces based on a bandwidth of the plugged one of the at least one PCIe CEM slot through a MCIO connection line, by the at least two test-card MCIO connection interface;
electrically connecting the PCIe chip to the at least two test-card MCIO connection interface, the test-card serial data communication standard interface and the test-card network connection interface;
providing an external test device comprising a device serial-data communication standard interface, a device network connection interface, a device storage unit and a device central-processing unit;
electrically connecting the device serial-data communication standard interface to the test-card serial data communication standard interface;
electrically connecting the device network connection interface to the test-card network connection interface;
storing a test program in the device storage unit;
electrically connecting the device central-processing unit to the device serial-data communication standard interface, the device network connection interface and the device storage unit;
loading and executing the test program stored in the storage unit, by the device central-processing unit;
generating a differential signal by the central processing unit;
providing the differential signal to the PCIe CEM plug interface, through one of the at least one PCIe CEM slot, by the central processing unit;
providing the differential signal, obtained by the PCIe CEM plug interface, to the adapter MCIO connection interface by the communication unit;
obtaining the differential signal from the connected adapter MCIO connection interface, by the at least two test-card. MCIO connection interface;
generating differential status information by the PCIe chip, according to the differential signal obtained by the test-card MCIO connection interface; and
obtaining the differential status information from the PCIe chip, through at least one of the device serial-data communication standard interface and the device network connection interface, by the test program, to implement detection of the differential signal of the at least one PCIe CEM slot.

4. The detection method for PCIe CEM connection interface of circuit board according to claim 3, wherein each of the at least one test adapter card comprises a test logic circuit, the test logic circuit is electrically connected to the communication unit, and the detection method comprises:
generating and providing a detection signal to the test logic circuit of the test adapter card through the test card, by the test program;
performing detection based on the detection signal, to generate a detection result, or performing detection for slot status reading, power-pin voltage measurement and/or wake signal transmission on corresponding one of the at least one PCIe CEM slot through a PCIe CEM plug interface based on the detection signal, to generate the detection result, by the test logic circuit; and
providing the detection result to the test program through the test card, by the test adapter card.
